(19) United States
(12) Patent Application Publication
(10) Pub. No.: US 2026/0090089 A1
(43) Pub. Date: Mar. 26, 2026

(54) MULTI-GATE DEVICE STRUCTURE AND METHODS THEREOF

(71) Applicant: Taiwan Semiconductor Manufacturing Company, Ltd., Hsinchu (TW)

(72) Inventors: Hsien-Chih Huang, Hsinchu City (TW); Guan-Lin Chen, Hsinchu County (TW); Kuo-Cheng CHIANG, Hsinchu County (TW); Chih-Hao Wang, Hsinchu County (TW); Wei-Hsuan Lin, Hsinchu County (TW)

(21) Appl. No.: 19/080,163

(22) Filed: Mar. 14, 2025

Related U.S. Application Data
(60) Provisional application No. 63/699,451, filed on Sep. 26, 2024.

(51) Int. Cl. H10D 84/85; H10D 30/00; H10D 30/01; H10D 30/43; H10D 62/10; H10D 62/13; H10D 64/01; H10D 64/27; H10D 64/66; H10D 84/01

(52) U.S. Cl. CPC H10D 84/851; H10D 30/014; H10D 30/0191; H10D 30/43; H10D 30/503; H10D 62/102; H10D 62/121; H10D 62/151; H10D 64/017; H10D 64/018; H10D 64/021; H10D 64/516; H10D 64/675; H10D 84/0172; H10D 84/0184

(57) ABSTRACT

A device includes a plurality of nanosheets over a substrate, a source/drain feature adjacent to the plurality of nanosheets, and a gate structure disposed over the plurality of nanosheets and between adjacent nanosheets. Gate spacers are disposed over sidewalls of opposing sides of a top portion of the gate structure. Inner spacers interpose lateral ends of adjacent ones of the plurality of nanosheets in a first direction and interpose portions of the gate structure and the source/drain feature in a second direction. Each of the inner spacers includes a core layer and a liner layer disposed on a top and bottom surfaces of the core layer. There is an offset of a dimension of the plurality of nanosheets in a third direction at an interface between portions of the nanosheets underneath the gate spacers and portions of the nanosheets underneath the top portion of the gate structure.

### CROSS-REFERENCE TO RELATED APPLICATION

This application claims the benefit of U.S. Provisional Application No. 63/699,451, filed Sep. 26, 2024, the entirety of which is incorporated by reference herein.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the fin field-effect transistor (FinFET). The FinFET gets its name from the fin-like structure which extends from a substrate on which it is formed, and which is used to form the FET channel. Another multi-gate device, introduced in part to address performance challenges associated with FinFETs, is the gate-all-around (GAA) transistor. GAA transistors get their name from the gate structure which extends completely around the channel, providing better electrostatic control than FinFETs. FinFETs and GAA transistors are compatible with conventional complementary metal-oxide-semiconductor (CMOS) processes and their three-dimensional structure allows them to be aggressively scaled while maintaining gate control and mitigating SCEs.

In general, GAA transistors may be implemented, for example, in cases where FinFETs can no longer meet performance requirements. However, fabrication of GAA transistors has introduced new challenges to the semiconductor manufacturing process and has led to associated device reliability concerns. Thus, existing techniques have not proved entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 provides a simplified top-down layout view of a multi-gate device, in accordance with some embodiments;

FIG. 2 is a flow chart of a method of fabricating a semiconductor device 300 according to one or more aspects of the present disclosure;

FIGS. 3, 4, 5, 6, 7, 8, 9, 10, and 11 provide cross-sectional views of an embodiment of the semiconductor device 300, at different stages of fabrication in accordance with the method of FIG. 2, along a plane substantially parallel to a plane defined by section X-X′ of FIG. 1, in accordance with some embodiments;

FIG. 12A illustrates a cross-sectional view of a semiconductor device 1200 along a plane substantially parallel to the plane defined by section X-X′ of FIG. 1, and FIG. 12B illustrates a top-down cross-sectional view of the semiconductor device 1200 along a plane substantially parallel to the plane defined by section Z-Z′ of FIG. 12A, according to some embodiments;

FIG. 13A illustrates a cross-sectional view of a semiconductor device 1300 along a plane substantially parallel to the plane defined by section X-X′ of FIG. 1, and FIG. 13B illustrates a top-down cross-sectional view of the semiconductor device 1300 along a plane substantially parallel to the plane defined by section Z-Z′ of FIG. 13A, according to some embodiments;

FIG. 14A illustrates a cross-sectional view of a semiconductor device 1400 along a plane substantially parallel to the plane defined by section X-X′ of FIG. 1, and FIG. 14B illustrates a top-down cross-sectional view of the semiconductor device 1400 along a plane substantially parallel to the plane defined by section Z-Z′ of FIG. 14A, according to some embodiments; and

FIG. 15A illustrates a cross-sectional view of a semiconductor device 1500 along a plane substantially parallel to the plane defined by section X-X′ of FIG. 1, and FIG. 15B illustrates a top-down cross-sectional view of the semiconductor device 1500 along a plane substantially parallel to the plane defined by section Z-Z′ of FIG. 15A, according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Additionally, in the discussion that follows, dimensions (e.g., such as thickness, width, length, etc.) for a given layer or other feature may at times be described using terms such as “substantially equal”, “equal”, or “about”, where such terms are understood to mean within +/−10% of the recited value or between compared values. For instance, if dimension A is described as being “substantially equal” to dimension B, it will be understood that dimension A is within +/−10% of dimension B. As another example, if a layer is described as having a thickness of about 100 nm, it will be understood that the thickness of the layer may in a range between 90-110 nm.

It is also noted that the present disclosure presents embodiments in the form of multi-gate transistors which may be employed in any of a variety of device types and/or circuit types. Multi-gate transistors include those transistors whose gate structures are formed on at least two-sides of a channel region. These multi-gate devices may include a P-type transistor or an N-type transistor. Some examples of multi-gate devices include fin field-effect transistors (FinFETs), where such devices include fins extending from a substrate (or nanostructures extending from a substrate), and where the fins are composed of a substantially uniform composition. Other examples of multi-gate devices, an in particular examples of multi-gate devices that are presented herein, include gate-all-around (GAA) transistors. A GAA transistor includes any device that has its gate structure, or portion thereof, formed on 4-sides of a channel region (e.g., surrounding a portion of a channel region). Devices presented herein also include embodiments that have channel regions disposed in various nanostructures such as nanosheet channel(s), nanowire channel(s), bar-shaped channel(s), and/or other suitable channel configurations. Presented herein are embodiments of devices that may have one or more nanostructured channel regions (e.g., nanowires/nanosheets) associated with a single, contiguous gate structure. GAA devices may include a plurality of stacked channel layers (e.g., a plurality of stacked nanosheets or stacked nanostructures) that form the channels of a GAA transistor. However, one of ordinary skill would recognize that the teachings disclosed herein can apply to a single channel (e.g., single nanowire/nanosheet/nanostructure) or any number of channels. One of ordinary skill may recognize other examples of semiconductor devices that may benefit from aspects of the present disclosure.

At a certain stage of fabrication of GAA devices, a fin structure is formed that includes a plurality of stacked channel layers (which may include Si layers) interposed by a plurality of dummy layers (which may include SiGe layers), and a dummy gate (e.g., a polysilicon gate) is formed over the fin. In some existing implementations, source/drain features are then formed in source/drain regions and the dummy gate is removed. After removal of the dummy gate, and in some examples, a sheet formation process is performed to remove the dummy layers (SiGe layers), while the Si channel layers (or Si nanosheets) remain and gaps are formed between adjacent ones of the Si channel layers. In various examples, a high-K/metal gate structure may then be formed over the Si channel layers and in the gaps between adjacent ones of the Si channel layers. In particular, by performing the sheet formation process after removal of the dummy gate, several issues may arise. For example, the dummy layers (SiGe layers) induce tensile strain in the channel layers, which compensates the compressive strain generated from SiGe P-type epitaxial source/drain features. In addition, the Si channel layers may suffer from loss of sheet width as a result of the formation process, thereby forming a bow tie-shaped channel. Further, there is a risk of damage to the P-type epitaxial source/drain features during the sheet formation process. In some cases, there is also a risk of metal gate protrusion. Thus, existing techniques have not proved entirely satisfactory in all respects.

Embodiments of the present disclosure offer advantages over the existing art, though it is understood that other embodiments may offer different advantages, not all advantages are necessarily discussed herein, and no particular advantage is required for all embodiments. For example, embodiments discussed herein include multi-gate device structures (e.g., such as a GAA transistor structures), and related methods, where the sheet formation process (e.g., removal of dummy layers) is performed at a source/drain loop stage of processing (e.g., before formation of inner spacers), leaving the gaps between adjacent Si channel layers empty after removal of the dummy layers (SiGe layers). After the sheet formation process, in accordance with some embodiments, the inner spacers are formed and the source/drain features are formed in the source/drain regions. Thereafter, the dummy gate is removed and a high-K/metal gate structure may then be formed over the Si channel layers and in the gaps between adjacent ones of the Si channel layers. Thus, embodiments of the present disclosure provide for sheet formation from a lateral direction towards source/drain regions instead of from a vertical direction towards the dummy gate (e.g., as in existing implementations). Aspects of the present disclosure provide various advantages including reduced loss of sheet width (of the Si channel layers) or wider sheet width (of the Si channel layers), increased strain in P-type transistor channels (leading to higher drive current), reduced bow tie-shape of the channels, reduced risk of metal gate protrusion (also leading to increased drive current), and less Nd effect for N-type transistors. Other embodiments and advantages will be evident to those skilled in the art upon reading the present disclosure.

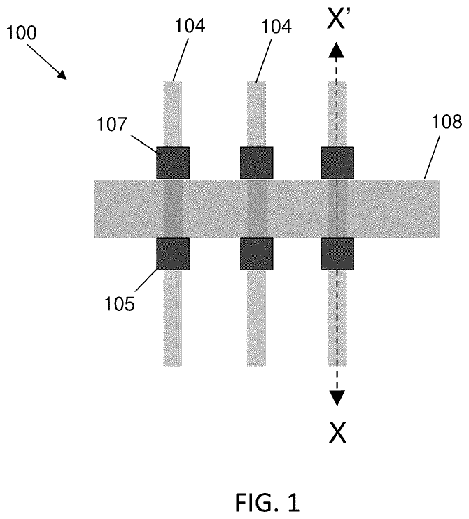

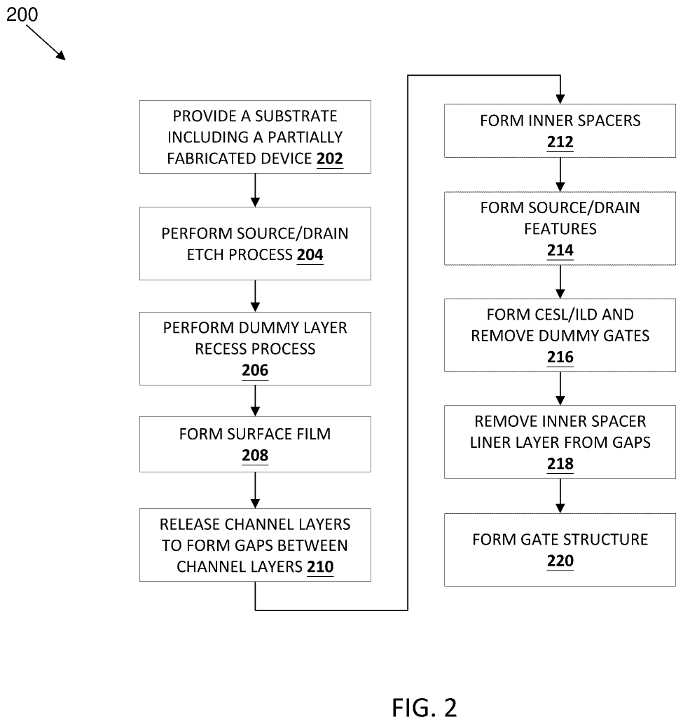

For purposes of the discussion that follows, FIG. 1 provides a simplified top-down layout view of a multi-gate device 100, for example, such as a GAA transistor. The multi-gate device 100 may include a plurality of fin elements 104 extending from a substrate, a gate structure 108 disposed over and around the fin elements 104, and source/drain regions 105, 107, where the source/drain regions 105, 107 are formed in, on, and/or surrounding the fins 104. A channel region of the multi-gate device 100, which may include a plurality of semiconductor channel layers (e.g., such as a plurality of stacked nanostructures or stacked nanosheets), is disposed within the fins 104, underlying the gate structure 108, along a plane substantially parallel to a plane defined by section X-X′ of FIG. 1. In some embodiments, sidewall spacers may also be formed on sidewalls of the gate structure 108. Various other features of the multi-gate device 100 are discussed in more detail below with reference to the method of FIG. 2 and associated device structures 300, 1200, 1300, 1400, and 1500.

Referring to FIG. 2, illustrated therein is an exemplary method 200 of semiconductor fabrication including fabrication of a semiconductor device 300 (e.g., which includes GAA transistors), in accordance with various embodiments. It will be understood that aspects of the method 200 may be equally applied to other types of multi-gate devices, or to other types of devices implemented by the multi-gate devices, without departing from the scope of the present disclosure. In some embodiments, the method 200 may be used to fabricate the multi-gate device 100, described above with reference to FIG. 1. Thus, one or more aspects discussed above with reference to the multi-gate device 100 may also apply to the method 200. It is understood that the method 200 includes steps having features of a complementary metal-oxide-semiconductor (CMOS) technology process flow and thus, are only described briefly herein. Also, additional steps may be performed before, after, and/or during the method 200.

It is further noted that, in some embodiments, the semiconductor device 300 may include various other devices and features, such as other types of devices such as additional transistors, bipolar junction transistors, resistors, capacitors, inductors, diodes, fuses and/or other logic circuits, etc., but is simplified for a better understanding of the inventive concepts of the present disclosure. In some embodiments, the semiconductor device 300 include a plurality of semiconductor devices (e.g., transistors) which may be interconnected. Moreover, it is noted that the process steps of method 200, including any descriptions given with reference to the figures are merely exemplary and are not intended to be limiting beyond what is specifically recited in the claims that follow.

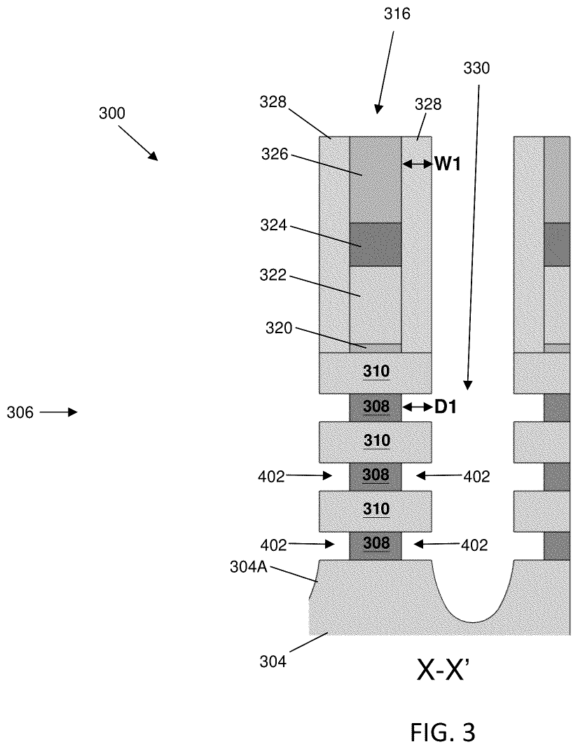

The method 200 begins at block 202 where a substrate including a partially fabricated device is provided. Referring to the example of FIG. 3, in an embodiment of block 202, a partially fabricated device 300 is provided. FIGS. 3-11 provide cross-sectional views of an embodiment of the semiconductor device 300, at different stages of fabrication in accordance with the method 200, along a plane substantially parallel to a plane defined by section X-X′ of FIG. 1 (e.g., along the direction of a fin 306). The device 300 may be formed on a substrate 304. In some embodiments, the substrate 304 may be a semiconductor substrate such as a silicon substrate. The substrate 304 may include various layers, including conductive or insulating layers formed on a semiconductor substrate. The substrate 304 may include various doping configurations depending on design requirements as is known in the art. The substrate 304 may also include other semiconductors such as germanium, silicon carbide (SiC), silicon germanium (SiGe), or diamond. Alternatively, the substrate 304 may include a compound semiconductor and/or an alloy semiconductor. Further, the substrate 304 may optionally include an epitaxial layer (epi-layer), may be strained for performance enhancement, may include a silicon-on-insulator (SOI) structure, and/or have other suitable enhancement features.

As shown in FIG. 3, the device 300 includes the fin 306 having a substrate portion 304A (formed from the substrate 304), epitaxial layers 308 of a first composition and epitaxial layers 310 of a second composition that interpose the layers 308 of the first composition. The epitaxial layers 308 of the first composition may also be referred to as nanostructures or nanosheets of the first composition, and epitaxial layers 310 of the second composition may also be referred to as nanostructures or nanosheets of the second composition. In some cases, shallow trench isolation (STI) features may be formed to isolate the fin 306 from neighboring fins. For purposes of this discussion, the epitaxial layers 308 of the first composition include the above-mentioned dummy layers, and the epitaxial layers 310 of the second composition include the above-mentioned semiconductor channel layers. In an embodiment, the epitaxial layers 308 of the first composition include SiGe and the epitaxial layers of the second composition 310 include silicon (Si). It is also noted that while the layers 308, 310 are shown as having a particular stacking sequence within the fin 306, where the layer 310 is the topmost layer of the stack of layers 308, 310, other configurations are possible. For example, in some cases, the layer 308 may alternatively be the topmost layer of the stack of layers 308, 310. Stated another way, the order of growth for the layers 308, 310, and thus their stacking sequence, may be switched or otherwise be different than what is shown in the figures, while remaining within the scope of the present disclosure.

In various embodiments, the epitaxial layers 310 (e.g., including the second composition), or portions thereof, may form a channel region of a GAA transistor of the device 300. For example, as noted above, the layers 310 may be referred to as semiconductor channel layers that are used to form a channel region of a GAA transistor. In various embodiments, the semiconductor channel layers (e.g., the layers 310 or portions thereof) may include various stacked nanostructures such as nanosheet channel(s), nanowire channel(s), bar-shaped channel(s), and/or other suitable channel configurations. The semiconductor channel layers may also be used to form portions of the source/drain features of the GAA transistor, in some embodiments.

It is noted that while the fin 306 is illustrated as including three (3) layers of the epitaxial layer 308 and three (3) layers of the epitaxial layer 310, this is for illustrative purposes only and not intended to be limiting beyond what is specifically recited in the claims. It can be appreciated that any number of epitaxial layers can be formed, where for example, the number of epitaxial layers depends on the desired number of semiconductor channel layers for the GAA transistor. In some embodiments, the number of epitaxial layers 310, and thus the number of semiconductor channel layers, is between 3 and 10.

In some embodiments, the epitaxial layers 308 (the dummy layers) each have a thickness in a range of about 3-15 nanometers (nm). In some cases, the epitaxial layers 310 (the semiconductor channel layers) each have a thickness in a range of about 3-15 nm. As noted above, the epitaxial layers 310 may serve as channel region(s) for a subsequently-formed multi-gate device (e.g., a GAA transistor) and its thickness may be chosen based at least in part on device performance considerations. The epitaxial layers 308 may serve to define a gap distance between adjacent channel region(s) for the subsequently-formed multi-gate device and its thickness may also be chosen based at least in part on device performance considerations. In some embodiments, the thickness of the epitaxial layers 310 (the semiconductor channel layers) may be less than the thickness of the epitaxial layers 308 (the dummy layers). In some examples, a ratio of thicknesses between a semiconductor channel layer (epitaxial layer 310) and a dummy layer (epitaxial layer 308) may be in a range of about ¼ to about ⅔. In some cases, the dummy layer (epitaxial layer 308) may be at least twice as thick as the semiconductor channel layer (epitaxial layer 310). Generally, the dummy layer (epitaxial layer 308) thickness is between about 25% to about 200% of the semiconductor channel layer (epitaxial layer 310) thickness.

The device 300 further includes gate stacks 316 formed over the fin 306. In an embodiment, the gate stacks 316 are dummy (sacrificial) gate stacks that are subsequently removed and replaced by a final gate stack at a subsequent processing stage of the device 300. For example, the gate stacks 316 may be replaced at a later processing stage by a high-K dielectric layer (HK) and metal gate electrode (MG). While the present discussion is directed to a replacement gate (gate-last) process whereby a dummy gate structure is formed and subsequently replaced, other configurations may be possible (e.g., such as a gate-first process). The portion of the fin 306 underlying the gate stacks 316 may be referred to as the channel region of the device 300. The gate stacks 316 may also define a source/drain region of the fin 306, for example, the regions of the fin 306 adjacent to and on opposing sides of the channel region.

In some embodiments, the gate stacks 316 include a dielectric layer 320 and an electrode layer 322 over the dielectric layer 320. In some cases, the gate stacks 316 may also include one or more hard mask layers 324, 326 formed over the electrode layer 322. In some embodiments, the dielectric layer 320 includes silicon oxide. Alternatively, or additionally, the dielectric layer 320 may include silicon nitride, a high-K dielectric material or other suitable material. In some embodiments, the electrode layer 322 may include polycrystalline silicon (polysilicon). In some embodiments, the hard mask layer 324 may include a nitride layer, and the hard mask layer 326 may include an oxide layer. By way of example, the nitride of the hard mask layer 324 may be a pad nitride layer that may include Si₃N₄, silicon oxynitride or silicon carbide. In some embodiments, the oxide of the hard mask layer 326 may be a pad oxide layer that may include SiO₂.

In some embodiments, one or more spacer layers 328 may be formed on sidewalls of the gate stacks 316. In some cases, the one or more spacer layers 328 may include a dielectric material such as silicon oxide, silicon nitride, silicon carbide, silicon oxynitride, SiCN, silicon oxycarbide, SiOCN, a low-K material (e.g., with a dielectric constant ‘k’<7), and/or combinations thereof. In some embodiments, the one or more spacer layers 328 include multiple layers, such as main spacer layers, liner layers, and the like. It is noted that, in various embodiments, portions of the epitaxial layers 310 (the semiconductor channel layers) disposed beneath the one or more spacer layers 328 may be defined as an LDD region of the device 300.

The method 200 then proceeds to block 204 where a source/drain etch process is performed. Still with reference to FIG. 3, in an embodiment of block 204, a source/drain etch process is performed to the device 300. In some embodiments, the source/drain etch process is performed to remove the exposed epitaxial layers 308, 310 in source/drain regions of the device 300 to form trenches 330 which expose underlying portions of the substrate 304. The source/drain etch process also serves to expose lateral surfaces of the epitaxial layers 308, 310. In some embodiments, the source/drain etch process may also remove portions of the one or more spacer layers 328 (e.g., from top surfaces of the gate stacks 316). In some embodiments, the source/drain etch process may include a dry etching process, a wet etching process, and/or a combination thereof.

The method 200 then proceeds to block 206 where a dummy layer recess process is performed. Still referring to FIG. 3, in an embodiment of block 206, a dummy layer recess process is performed to the device 300. The dummy layer recess process includes a lateral etch of the epitaxial layers 308 (the dummy layers) to form recesses 402 along sidewalls of the previously formed trenches 330. In some embodiments, the dummy layer recess process is performed using a dry etching process, a wet etching process, and/or a combination thereof. In some cases, the dummy layer recess process may include etching using a standard clean 1 (SC-1) solution, ozone (O₃), a solution of ammonium hydroxide (NH₄OH), hydrogen peroxide (H₂O₂) and water (H₂O), hydrofluoric acid (HF), buffered HF, and/or a fluorine (F₂)-based etch. In some examples, the F₂-based etch may include an F₂ remote plasma etch. In some cases, a depth ‘D1’ of the recesses 402 may be substantially equal to a width ‘W1’ of the one or more spacer layers 328. During subsequent stages of processing, as discussed below, the epitaxial layers 308 (the dummy layers) will be removed and replaced by portions of a gate structure (e.g., a metal gate structure). In various examples, the replacement gate structure will interface inner spacers, or portions thereof, as also described in more detail below.

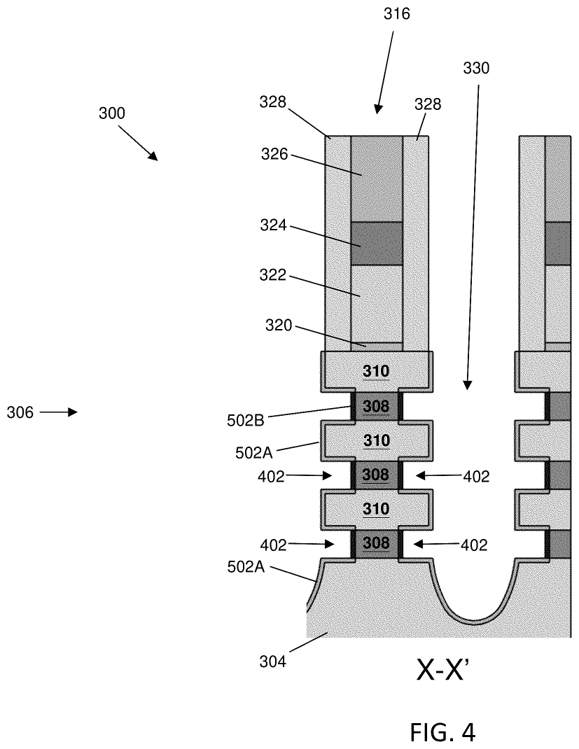

The method 200 then proceeds to block 208 where a surface film is formed. Referring to FIG. 3 and FIG. 4, in an embodiment of block 208, a surface film 502 may be formed. In particular, the surface film 502 may be formed along exposed lateral surfaces of the epitaxial layers 310, on exposed top and/or bottom surfaces of the epitaxial layers 310 within the recesses 402, on exposed lateral surfaces of the recessed epitaxial layers 308, and on exposed surfaces of the substrate portion 304A, which may include a bottom surface of the trenches 330. In some embodiments, the surface film 502 is a porous film configured to have a sufficient porosity so as to allow an etchant to pass through (penetrate) the porous film to selectively remove the epitaxial layers 308 during a subsequent channel layer release process, as discussed below. In some cases, the surface film 502 may thus be equivalently referred to as the porous surface film 502. In various examples, the porous surface film 502 may be an oxide layer (e.g., such as a silicon oxide layer), a SiN layer, a SiCON layer, or a combination thereof. More generally, in various embodiments, the porous surface film 502 may include silicon (Si), carbon (C), oxygen (O), nitrogen (N), or a combination thereof.

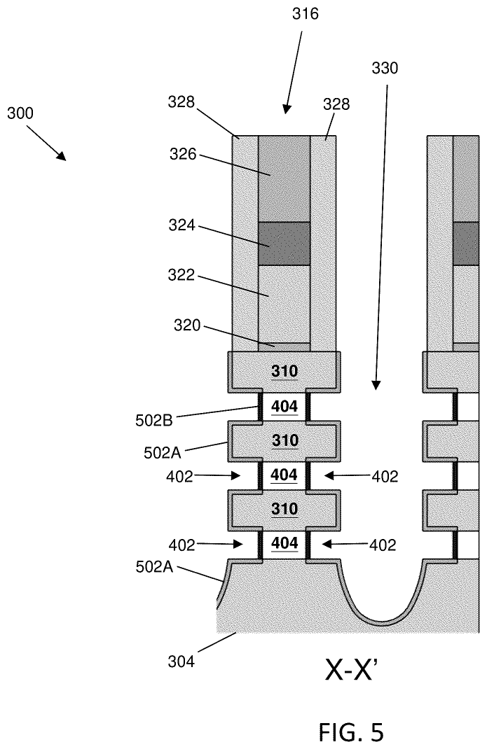

The method 200 then proceeds to block 210 where a channel layer release process (or sheet formation process) is performed. Referring to the example of FIG. 4 and FIG. 5, in an embodiment of block 210, while the dummy gate stacks 316 remain in place, the dummy layers (the epitaxial layers 308) in the channel region of the device 300 may be selectively removed (e.g., using a selective etching process), while the semiconductor channel layers (the epitaxial layers 310) remain unetched. In some cases, removal of the dummy layers (the epitaxial layers 308) may partially etch top and/or bottom surfaces of the epitaxial layers 310 (semiconductor channel layers) within the channel region of the device 300, such that the semiconductor channel layers are slightly thinner in the channel region as compared to the LDD region. In some examples, such consumption of portions of the epitaxial layers 310 during the selective etching process to remove the dummy layers may occur due to intermixing of the epitaxial layers 308/310 at an interface between the epitaxial layers 308 and the epitaxial layers 310.

In some examples, selective removal of the dummy layers (the epitaxial layers 308) may be referred to as a channel layer release process (e.g., as the semiconductor channel layers are released from the dummy layers). The selective etching process may be performed through the trenches 330 (in source/drain regions) such that sheet formation (or channel release) occurs from a lateral direction towards the source/drain regions instead of from a vertical direction towards the dummy gate stack 316. In particular, as noted above, the selective etching process used to remove the epitaxial layers 308 may include use of an etchant that passes through (penetrates) the porous surface film 502 to selectively remove the epitaxial layers 308. In various examples, the etch selectivity between the porous surface film 502 and the epitaxial layers 308 is very high, such as between about 100-300. As a result, the epitaxial layers 308 can be effectively removed without etching or damaging the porous surface film 502. The selective etching process, configured for selective removal of the epitaxial layers 308, will also leave other surrounding layers (such as the epitaxial layers 310) substantially unetched. In some embodiments, the selective etching process may include a selective wet etching process. In some cases, the selective wet etching includes ammonia and/or ozone. As merely one example, the selective wet etching process includes tetra-methyl ammonium hydroxide (TMAH). To be sure, in some cases, the selective etching process may include a selective dry etching process. It is noted that as a result of the selective removal of the dummy layers (the epitaxial layers 308), gaps 404 may be formed between the adjacent semiconductor channel layers (the epitaxial layers 310) in the channel region. By way of example, the gaps 404 may serve to expose portions of the epitaxial layers 310 between opposing portions of the porous surface film 502 (previously disposed on exposed lateral surfaces of the recessed epitaxial layers 308). As described in more detail below, portions of gate structures for the device 300 will be formed within the gaps 404.

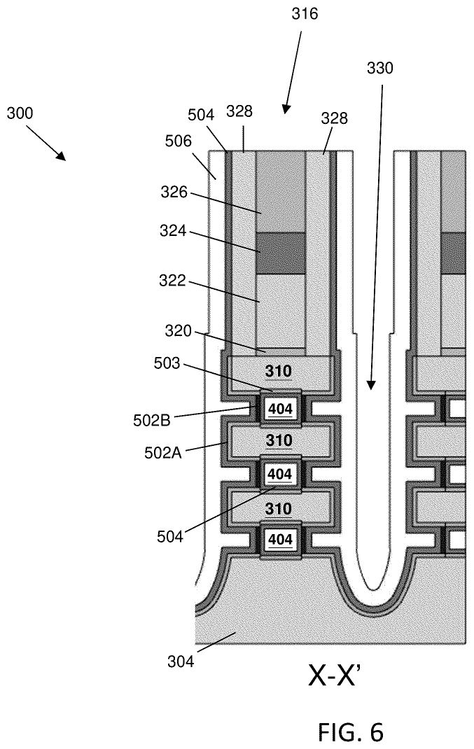

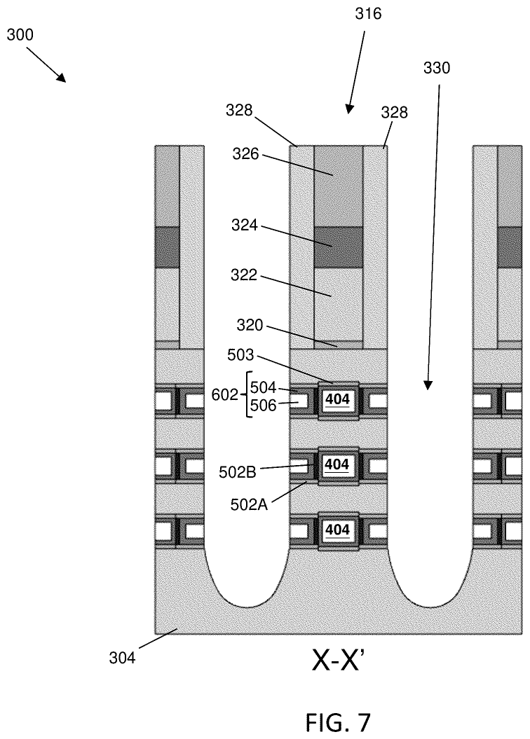

The method 200 then proceeds to block 212 where inner spacers are formed. Referring to FIG. 5, FIG. 6, and FIG. 7, in an embodiment of block 212, an inner spacer liner layer 504 is initially deposited over the device 300, within the trenches 330 and within the recesses 402. In particular, the inner spacer liner layer 504 may be deposited over the previously formed porous surface film 502. In some examples, a precursor used to form the inner spacer liner layer 504 may pass through (penetrate) the porous surface film 502, resulting in the inner spacer liner layer 504 also being formed along surfaces within the gaps 404 (e.g., surfaces of adjacent epitaxial layers 310 and portions of the porous surface film 502). To be sure, in some embodiments, the precursor used to form the inner spacer liner layer 504 may not pass through (penetrate) the porous surface film 502, and thus the inner spacer liner layer 504 may not be formed along surfaces within the gaps 404. In various examples, the inner spacer liner layer 504 may have a thickness in a range of about 0.2-1 nm. In some embodiments, the inner spacer liner layer 504 may include silicon oxide (SiOx), silicon germanium oxide (SiGeOx), silicon nitride (SiN), silicon carbonitride (SiCN), or silicon carbon oxynitride (SiCON). In various embodiments, the inner spacer liner layer 504 may have a dielectric constant ‘k’ in a range between about 4-7 or in a range between about 3-6. In some cases, formation of the inner spacer liner layer 504 may additionally result in the formation of an interfacial layer 503 (or interfacial oxide layer 503) along surfaces of the epitaxial layers 310 facing the gaps 404.

After deposition of the inner spacer liner layer 504, and in a further embodiment of block 212, an inner spacer core layer 506 is deposited over the device 300, within the trenches 330 and within the recesses 402. In particular, the inner spacer core layer 506 may be deposited over the previously deposited inner spacer liner layer 504. In some cases, the inner spacer core layer 506 may have a thickness in a range of about 0.2-8 nm. In some embodiments, the inner spacer core layer 506 may include silicon oxide (SiOx), silicon nitride (SiN), silicon carbonitride (SiCN), or silicon carbon oxynitride (SiCON). In various embodiments, the inner spacer core layer 506 may have a dielectric constant ‘k’ in a range between about 4-7. By way of example, the inner spacer liner layer 504 and the inner spacer core layer 506 may be formed by conformal deposition over the device 300 using processes such as a CVD process, a subatmospheric CVD (SACVD) process, a flowable CVD process, an ALD process, a PVD process, or other suitable process.

After deposition of the inner spacer liner layer 504 and the inner spacer core layer 506, and in a further embodiment of block 212, an inner spacer etch-back process may be performed. In various examples, the inner spacer etch-back process etches the inner spacer liner layer 504 and the inner spacer core layer 506 from over a top surface of the device 300 and along sidewalls of the trenches 330, while the inner spacer liner layer 504 and the inner spacer core layer 506 remain disposed within the recesses 402, thereby providing inner spacers 602 for the device 300. In some embodiments, the inner spacer etch-back process may also remove the surface film 502 disposed on lateral surfaces of the epitaxial layers 310, thereby exposing the lateral surfaces of the epitaxial layers 310 within the trenches 330. By way of example, the inner spacer etch-back process may be performed using a wet etch process, a dry etch process, or a combination thereof. In some cases, any residual portions of the inner spacer liner layer 504, the inner spacer core layer 506, and the surface film 502 that remain on top surfaces of the device 300 and/or on sidewalls or bottom surfaces of the trenches 330, for example after the inner spacer etch-back process, may be removed during subsequent processes (e.g., prior to epitaxial growth of source/drain features). In various examples, the inner spacers 602 may extend beneath the one or more spacer layers 328 (formed on sidewalls of the gate stacks 316) while being disposed adjacent to subsequently formed source/drain features, as described below. In some cases, the inner spacers 602 may extend at least partially beneath the gate stacks 316.

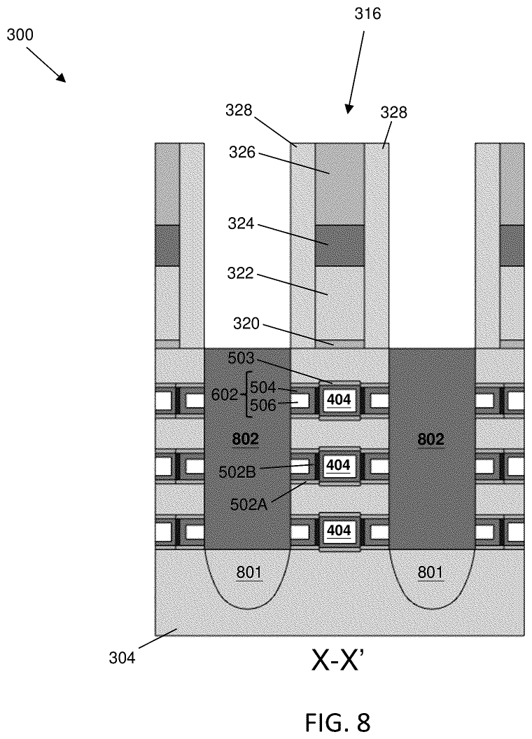

The method 200 then proceeds to block 214 where source/drain features are formed. Referring to FIG. 7 and FIG. 8, in an embodiment of block 214, source/drain features 801, 802 are formed. In some embodiments, the source/drain features 801, 802 are formed in source/drain regions adjacent to and on either side of the gate stacks 316 of the device 300. For example, the source/drain features 801, 802 may be formed within the trenches 330 of the device 300, with the source/drain features 801 over the exposed portions of the substrate 304, and with the source/drain features 802 over the source/drain features 801, and the source/drain features 802 in contact with the lateral surfaces of the epitaxial layers 310 (semiconductor channel layers) and adjacent to (or in some cases in contact with) the inner spacers 602. In some embodiments, a clean process may be performed immediately prior to formation of the source/drain features 801, 802. The clean process may include a wet etch, a dry etch, or a combination thereof. In addition, the clean process may remove any residual portions of the inner spacer liner layer 504, the inner spacer core layer 506, and the surface film 502 that remained on top surfaces of the device 300 and/or on sidewalls or bottom surfaces of the trenches 330 (e.g., after the inner spacer etch-back process).

In some embodiments, the source/drain features 801, 802 are formed by epitaxially growing a semiconductor material layer in the source/drain regions. In some cases, the source/drain features 801 may include undoped silicon, undoped SiGe, or a lightly-doped layer (e.g., such as lightly boron-doped SiGe for P-type source/drain features or lightly arsenic-doped SiP for N-type source/drain features) to prevent out-diffusion and/or suppress leakage current. In some cases, the source/drain features 801 may additionally or alternatively include a SiC layer to suppress leakage current. The source/drain features 802 may include a more heavily-doped layer than the source/drain features 801 (e.g., such as heavily boron-doped SiGe for P-type source/drain features or heavily arsenic-doped SiP for N-type source/drain features) to provide reduced source/drain contact resistance. Generally, and in various embodiments, the semiconductor material layer grown to form the source/drain features 801, 802 may include Ge, Si, GaAs, AlGaAs, SiGe, GaAsP, SiP, or other suitable material. The source/drain features 801, 802 may be formed by one or more epitaxial (cpi) processes. In some embodiments, the source/drain features 801, 802 may be in-situ doped during the epi process. By way of example, and in some embodiments, epitaxially grown SiGe source/drain features may be doped with boron. In some cases, epitaxially grown Si epi source/drain features may be doped with carbon to form Si:C source/drain features, phosphorous to form Si:P source/drain features, or both carbon and phosphorous to form SiCP source/drain features. In some embodiments, the source/drain features 801, 802 are not in-situ doped, and instead an implantation process is performed to dope the source/drain features 801, 802.

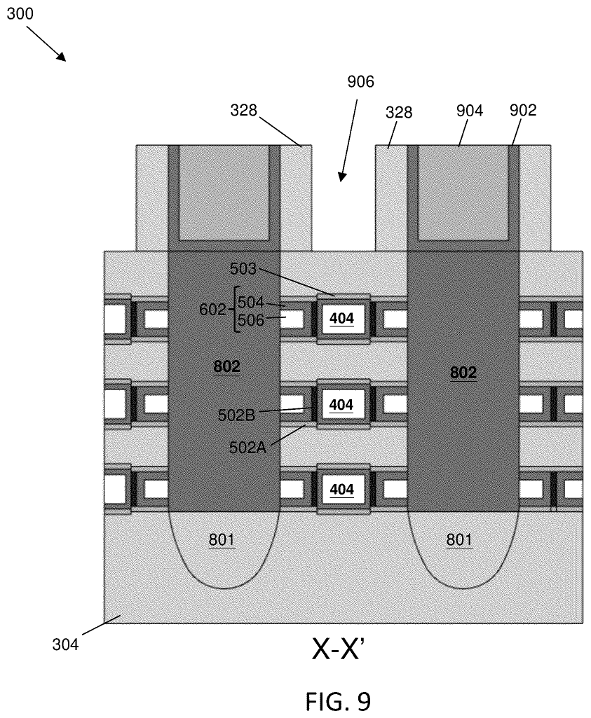

The method 200 proceeds to block 216 where a contact etch stop layer (CESL) and an inter-layer dielectric (ILD) layer are formed, and the dummy gates are removed. Referring to FIG. 8 and FIG. 9, in an embodiment of block 216, a CESL 902 may be formed over the device 300 and an ILD layer 904 may be formed over the CESL 902. In some examples, the CESL 902 may include a silicon nitride layer, a silicon oxide layer, a silicon oxynitride layer, and/or other materials known in the art. In some cases, the ILD layer 904 may include materials such as tetraethylorthosilicate (TEOS) oxide, un-doped silicate glass, or doped silicon oxide such as borophosphosilicate glass (BPSG), fluorosilicate glass (FSG), phosphosilicate glass (PSG), boron doped silicon glass (BSG), and/or other suitable dielectric materials. In some embodiments, after formation of the ILD layer 904, the device 300 may be subject to a high thermal budget process to anneal the ILD layer 904. In some embodiments, after formation of the CESL 902 and the ILD layer 904, a chemical mechanical polishing (CMP) process may be performed to remove portions of the ILD layer 904 and the CESL 902 overlying the gate stacks 316 to planarize a top surface of the device 300 and expose a top surface of the gate stacks 316 (e.g., including a top surface of the gate electrode layer 322). In some embodiments, the CMP process may remove the hard mask layers 326, 326 (if present) overlying the gate stacks 316 to expose the electrode layer 322. Still referring to FIG. 8 and FIG. 9, in a further embodiment of block 216, the dummy gates are removed. In particular, the exposed electrode layer 322 of the gate stacks 316 may initially be removed by suitable etching processes, followed by an etching process to remove the dielectric layer 320 from the gate stacks 316, thereby forming openings 906. In some examples, the etching processes may include a wet etch, a dry etch, or a combination thereof.

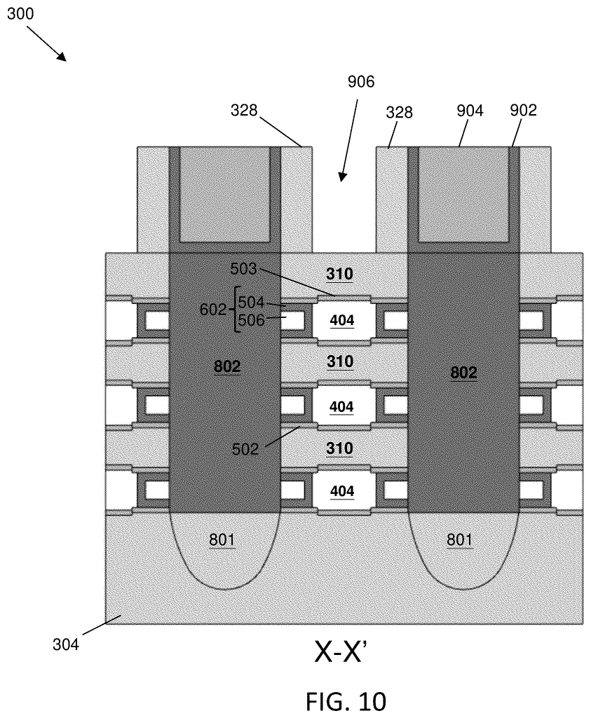

The method 200 then proceeds to block 218 where the inner spacer liner layer is removed from the gaps between channel layers. Referring to FIG. 9 and FIG. 10, in an embodiment of block 218, portions of the inner spacer liner layer 504 that are disposed on surfaces within the gaps 404 are etched, for example, by way of the openings 906. As a result of etching the inner spacer liner layer 504 within the gaps 404, the interfacial layer 503 (formed on surfaces of the epitaxial layers 310 facing the gaps 404) at top and bottom sides of the gaps 404 is exposed. In addition, etching of the inner spacer liner layer 504 within the gaps 404 may expose and etch the surface film 502 at lateral sides of the gaps 404, thereby exposing a surface of the inner spacers 602 (the exposed inner spacer 602 surface including a portion of the inner spacer liner layer 504 previously formed in the recesses 402). In some alternative embodiments, further etching may be performed to also remove a portion of the inner spacer 602 including the exposed portion of the inner spacer liner layer 504 previously formed in the recesses 402, thereby exposing the inner spacer core layer 506. In various examples, the etching processes may include a wet etch, a dry etch, or a combination thereof.

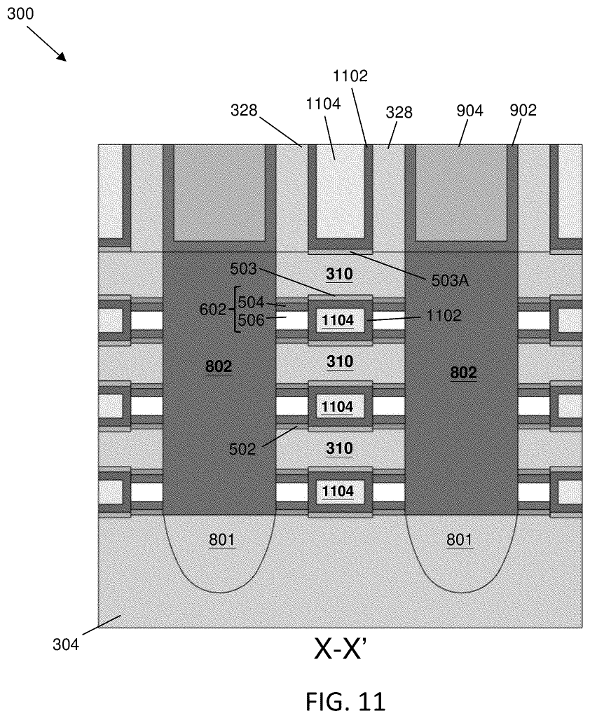

The method 200 proceeds to block 220 where a gate structure is formed. The gate structure may include a high-K/metal gate stack, however other compositions are possible. In some embodiments, the gate structure may form the gate associated with the multi-channels provided by the plurality of semiconductor channel layers (the epitaxial layers 310, now having gaps 404 therebetween) in the channel region of the device 300. Referring to FIG. 10 and FIG. 11, in an embodiment of block 220, a gate dielectric 1102 is deposited on exposed surfaces of the epitaxial layers 310 (semiconductor channel layers), including on the exposed portions of the epitaxial layers 310 within the gaps 404 and between opposing exposed surfaces of the inner spacers 602. In some cases, the gate dielectric 1102 may be deposited on the interfacial layer 503 (previously formed on surfaces of the epitaxial layers 310 facing the gaps 404). In a further embodiment of the block 200, an interfacial layer 503A, similar to the interfacial layer 503, may also be formed along a top surface of the topmost epitaxial layer 310, as shown. In some embodiments, the gate dielectric 1102 may include a high-K dielectric layer formed over respective ones of the interfacial layers 503, 503A. High-K gate dielectrics, as used and described herein, include dielectric materials having a high dielectric constant, for example, greater than that of thermal silicon oxide (˜3.9).

In some embodiments, the interfacial layers 503, 503A may include a dielectric material such as silicon oxide (SiO₂), HfSiO, or silicon oxynitride (SiON). In some examples, the high-K dielectric layer of the gate dielectric 1102 may include hafnium oxide (HfO₂). Alternatively, the high-K dielectric layer of the gate dielectric 1102 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTIO, (Ba,Sr)TiO₃ (BST), Al₂O₃, Si₃N₄, oxynitrides (SiON), combinations thereof, or other suitable material. In various embodiments, the interfacial layers 503, 503A and the gate dielectric 1102 may be formed by thermal oxidation, ALD, physical vapor deposition (PVD), pulsed laser deposition (PLD), CVD, and/or other suitable methods.

Still referring to the example of FIG. 11, and in a further embodiment of block 220, a metal gate including a metal layer 1104 is formed over the gate dielectric 1102. The metal layer 1104 may include a metal, metal alloy, or metal silicide. Additionally, the formation of the gate dielectric/metal gate stack may include depositions to form various gate materials, one or more liner layers, and one or more CMP processes to remove excessive gate materials and thereby planarize a top surface of the device 300.

In some embodiments, the metal layer 1104 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the metal layer 1104 may include Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or a combination thereof. In various embodiments, the metal layer 1104 may be formed by ALD, PVD, CVD, e-beam evaporation, or other suitable process. Further, the metal layer 1104 may be formed separately for N-type and P-type transistors which may use different metal layers. In addition, the metal layer 1104 may provide an N-type or P-type work function, may serve as a transistor (e.g., GAA transistor) gate electrode, and in at least some embodiments, the metal layer 1104 may include a polysilicon layer. With respect to the devices shown and discussed, the gate structure includes portions that interpose each of the epitaxial layers 310, which each provide semiconductor channel layers for GAA transistors.

Generally, the semiconductor device 300 may undergo further processing to form various features and regions known in the art. For example, further processing may form various contacts/vias/lines and multilayer interconnect features (e.g., metal layers and interlayer dielectrics) on the substrate 304, configured to connect the various features to form a functional circuit that may include one or more multi-gate devices (e.g., one or more GAA transistors). In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 200, and some process steps described above may be modified, replaced, or eliminated in accordance with various embodiments of the method 200.

It will be understood that the method 200, as discussed above, is merely exemplary, and the method 200 may be used to fabricate a variety of multi-gate device structures (e.g., such as a variety of GAA transistor structures), without departing from the scope of the present disclosure. By way of example, various embodiments of multi-gate device structures that may be fabricated in accordance with the method 200 are now discussed. It is noted that the differences shown and/or described below with respect to the various embodiments of multi-gate devices may be achieved by modifying, replacing, or eliminating one or more of the process steps of the method 200, while remaining in the scope of the present disclosure. In other cases, a same process step of the method 200 may be performed, but with different process parameters, to fabricate the desired embodiment of multi-gate device. Merely by way of example, such modification of process parameters may include variation of etch time, etch chemistry, or other relevant process parameter.

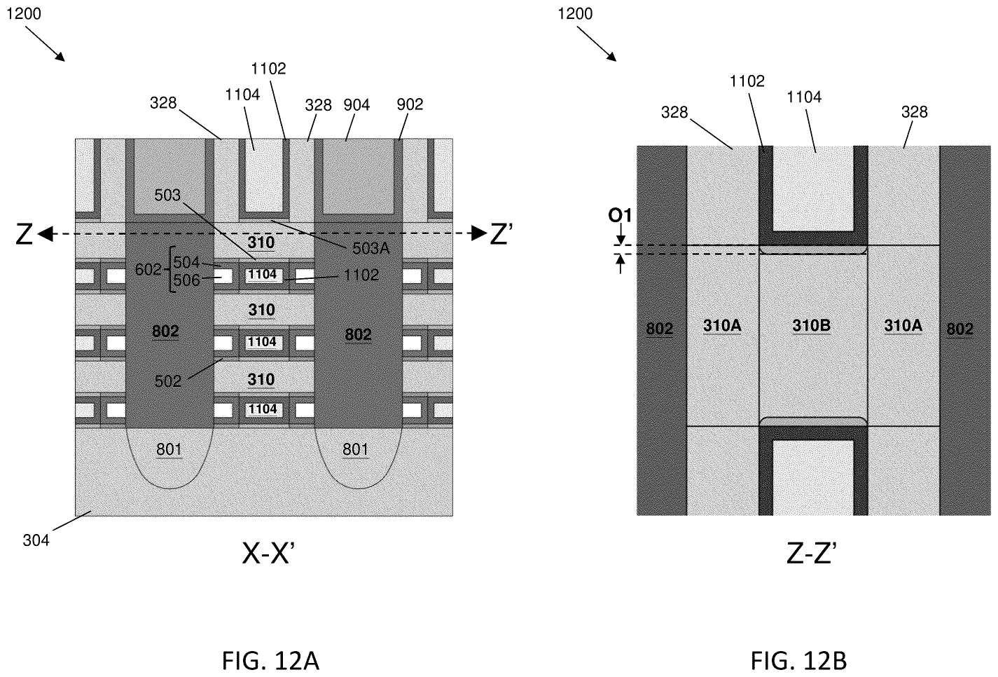

Referring first to FIG. 12A and FIG. 12B, illustrated therein is an embodiment of a semiconductor device 1200, similar to the semiconductor device 300 discussed above with reference to the method 200. In particular, FIG. 12A illustrates a cross-sectional view of the semiconductor device 1200 along a plane substantially parallel to the plane defined by section X-X′of FIG. 1, and FIG. 12B illustrates a top-down cross-sectional view of the semiconductor device 1200 along a plane substantially parallel to the plane defined by section Z-Z′ of FIG. 12A. For clarity of discussion, the semiconductor device 1200 is shown and described using like reference numbers to indicate like features, such as used above in the discussion of the semiconductor device 300.

As shown, the semiconductor device 1200 includes the epitaxial layers 310 (also referred to as semiconductor channel layers, nanostructures, or nanosheets) stacked over each other in a Z-direction (e.g., in a direction perpendicular to a top surface of an underlying substrate 304), where the epitaxial layers 310 may be as described above. In some examples, the semiconductor device 1200 further includes the source/drain features 802, which may be as described above, on opposite sides of the epitaxial layers 310 in an X-direction (e.g., on opposing sides of a channel region defined by the epitaxial layers 310). In some embodiments, the semiconductor device 1200 further includes a gate structure, which may include an interfacial layer (e.g., such as the interfacial layers 503, 503A), a high-K gate dielectric layer (e.g., such as the gate dielectric 1102), and a metal gate layer (e.g., such as the metal layer 1104), wrapping around the epitaxial layers 310, where the gate structure may be as described above. In some examples, the semiconductor device 1200 further includes the one or more spacer layers 328 (gate spacers) disposed over the epitaxial layers 310 and on sidewalls of a top portion of the gate structure. In some embodiments, the semiconductor device 1200 further includes the inner spacers 602 (composed of the inner spacer liner layer 504 and the inner spacer core layer 506) between lateral ends of adjacent epitaxial layers 310 in the Z-direction and interposing portions of the gate structure and the source/drain features 802 in the X-direction.

As shown in the exemplary embodiment of the semiconductor device 1200, the inner spacer liner layer 504 is a single, continuous layer that wraps around and is in contact with three sides (top side, bottom side, and one lateral side) of the inner spacer core layer 506. As a result, in the X-direction and on a first side of the inner spacers 602, the gate structure is in contact with the inner spacer liner layer 504 that is disposed on the lateral side of the inner spacer core layer 506, and on a second side of the inner spacers 602, the source/drain features 802 are in contact with both the inner spacer core layer 506 and portions of the inner spacer liner layer 504 disposed on top and bottom sides of the inner spacer core layer 506. As also shown, the surface film 502 may be disposed along and in contact with top and bottom surfaces of the inner spacers 602 (e.g., in contact with the inner spacer liner layer 504). In some examples, the surface film 502 may also be referred to as an oxide liner layer.

In some cases, the inner spacer liner layer 504 may have a thickness in a range of about 0.2-1 nm. In some embodiments, the inner spacer liner layer 504 may include silicon oxide (SiOx), silicon germanium oxide (SiGeOx), silicon nitride (SiN), silicon carbonitride (SiCN), or silicon carbon oxynitride (SiCON). Further, in some examples, the inner spacer core layer 506 may have a thickness in a range of about 0.2-8 nm. In some embodiments, the inner spacer core layer 506 may include silicon oxide (SiOx), silicon nitride (SiN), silicon carbonitride (SiCN), or silicon carbon oxynitride (SiCON). Additionally, in some examples, the surface film 502 may have a thickness in a range of about 0.2-1 nm. In various embodiments, the surface film 502 may include silicon oxide (SiOx), silicon nitride (SiN), silicon oxynitride (SiON), or other compositions, as discussed above.

Generally, in various embodiments, the inner spacer liner layer 504 may have a dielectric constant ‘k’ in a range between about 4-7 or in a range between about 3-6, and the inner spacer core layer 506 may have a dielectric constant ‘k’ in a range between about 4-7. In particular, in one example, both the inner spacer liner layer 504 and the inner spacer core layer 506 may have a dielectric constant ‘k’ in a range between about 4-7. In such a case, the higher range of dielectric constant ‘k’ for the inner spacer liner layer 504 provides for a harder inner spacer liner layer 504 and more structural stability. In another example, the inner spacer liner layer 504 may have a dielectric constant ‘k’ in a range between about 3-6, and the inner spacer core layer 506 may have a dielectric constant ‘k’ in a range between about 4-7. In such a case, the lower range of dielectric contact ‘k’ for the inner spacer liner layer 504 provides for reduced parasitic capacitance.

As further shown in FIG. 12A, in the embodiment of the semiconductor device 1200, there is substantially no offset (or substantially no change in width, or no bow tie structure) of a dimension of the epitaxial layers 310 in the Z-direction at an interface between the inner spacers 602 and the adjacent gate structure. In contrast, as shown in FIG. 12B, in the embodiment of the semiconductor device 1200, there is at least some offset ‘O1’ (or at least some change in width, or some bow tie structure) of a dimension of the epitaxial layers 310 in the Y-direction at an interface between a portion of the epitaxial layers 310A underneath the gate spacers 328 and a portion of the epitaxial layers 310B underneath the gate structure (e.g., the gate dielectric 1102 and the metal layer 1104). In some cases, the offset ‘O1’ may be in a range from about 0.2-1.5 nm. In various embodiments, the semiconductor device 1200 may also include other features, such as described above with reference to the semiconductor device 300.

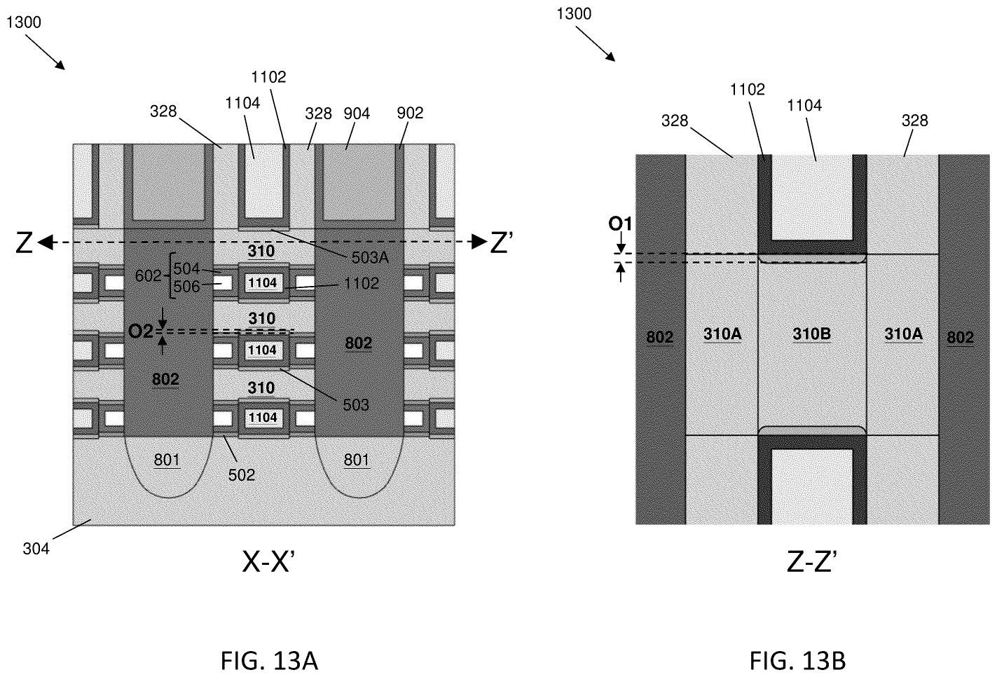

Referring next to FIG. 13A and FIG. 13B, illustrated therein is an embodiment of a semiconductor device 1300, similar to the semiconductor devices 300, 1200, discussed above. In particular, FIG. 13A illustrates a cross-sectional view of the semiconductor device 1300 along a plane substantially parallel to the plane defined by section X-X′ of FIG. 1, and FIG. 13B illustrates a top-down cross-sectional view of the semiconductor device 1300 along a plane substantially parallel to the plane defined by section Z-Z′ of FIG. 13A. For clarity of discussion, the semiconductor device 1300 is shown and described using like reference numbers to indicate like features, such as used above in the discussion of the semiconductor devices 300, 1200.

The embodiment of the semiconductor device 1300 is largely the same as the embodiment of the semiconductor device 1200, discussed above. However, in contrast to the semiconductor device 1200 and as shown in FIG. 13A, the semiconductor device 1300 includes at least some offset ‘02’ (or at least some change in width, or some bow tie structure) of a dimension of the epitaxial layers 310 in the Z-direction at the interface between the inner spacers 602 and the adjacent gate structure. In some examples, the offset ‘O₂’ may be in a range from about 0.2-1.5 nm. In addition, as shown in FIG. 13B, the semiconductor device 1300 also includes the offset ‘O1’ (or at least some change in width, or some bow tie structure) of a dimension of the epitaxial layers 310 in the Y-direction at the interface between the portion of the epitaxial layers 310A underneath the gate spacers 328 and the portion of the epitaxial layers 310B underneath the gate structure (e.g., the gate dielectric 1102 and the metal layer 1104). In some cases, the offset ‘O1’ may be in a range from about 0.2-1.5 nm. In various embodiments, the semiconductor device 1300 may also include other features, such as described above.

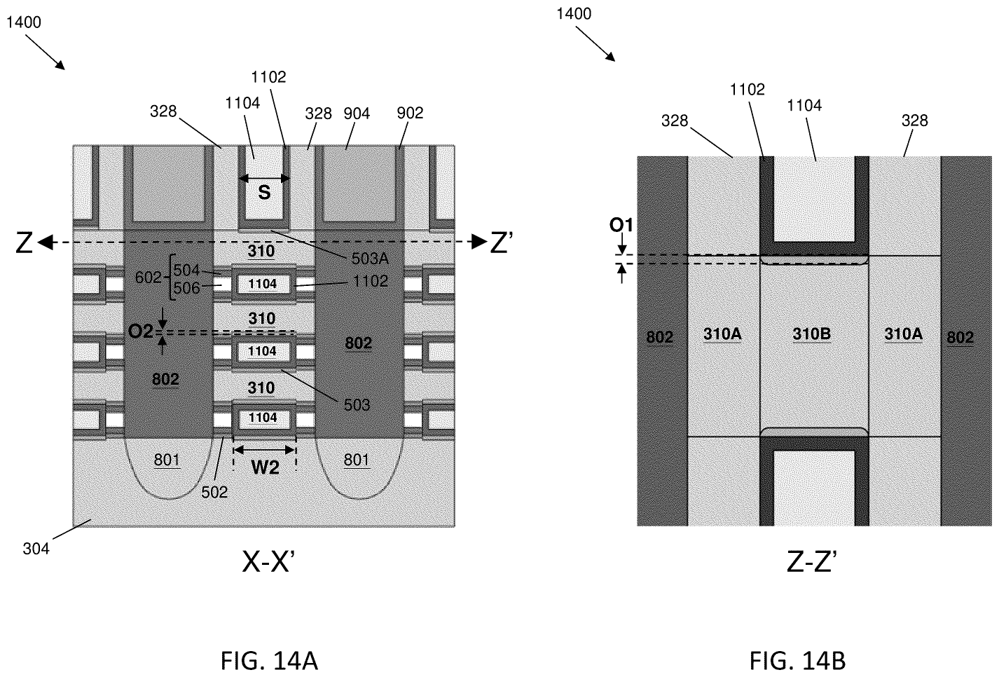

Referring now to FIG. 14A and FIG. 14B, illustrated therein is an embodiment of a semiconductor device 1400, similar to the semiconductor devices 300, 1200, 1300, discussed above. In particular, FIG. 14A illustrates a cross-sectional view of the semiconductor device 1400 along a plane substantially parallel to the plane defined by section X-X′ of FIG. 1, and FIG. 14B illustrates a top-down cross-sectional view of the semiconductor device 1400 along a plane substantially parallel to the plane defined by section Z-Z′ of FIG. 14A. For clarity of discussion, the semiconductor device 1400 is shown and described using like reference numbers to indicate like features, such as used above in the discussion of the semiconductor devices 300, 1200, 1300.

The embodiment of the semiconductor device 1400 is largely the same as the embodiment of the semiconductor device 1300, discussed above. However, in contrast to the semiconductor device 1300 and as shown in FIG. 14A, the inner spacer liner layer 504 of the semiconductor device 1400 is composed of a first portion that contacts a top side of the inner spacer core layer 506 and a second portion that contacts a bottom side of the inner spacer core layer 506. The inner spacer liner layer 504 of the semiconductor device 1400 is thus in contact with two sides (top side and bottom side) of the inner spacer core layer 506. In some embodiments, the lateral side of the inner spacer liner layer 504 that faces the gate structure (in the X-direction) may be etched (e.g., at block 218 of the method 200) to expose a lateral side of the inner spacer core layer 506. As a result, in the X-direction and on a first side of the inner spacers 602, the gate structure is in contact with the lateral side of the inner spacer core layer 506 and portions of the inner spacer liner layer 504 that are disposed on top and bottom sides of the inner spacer core layer 506, and on a second side of the inner spacers 602, the source/drain features 802 are in contact with both the inner spacer core layer 506 and portions of the inner spacer liner layer 504 disposed on top and bottom sides of the inner spacer core layer 506. As a further result, in the semiconductor device 1400 and in some embodiments, portions of the gate structure disposed between adjacent epitaxial layers 310 may have a width ‘W2’ that is greater than a spacing ‘S’ between gate spacers 328 on opposing sides of a top portion of the gate structure. Stated another way, in some embodiments, the portions of the gate structure disposed between adjacent epitaxial layers 310 may have lateral ends that extend into regions beneath the gate spacers 328. To be sure, in other cases where the gate structure is in contact with the lateral side of the inner spacer core layer 506 (e.g., as in the semiconductor device 300 shown in FIG. 11), portions of the gate structure disposed between adjacent epitaxial layers 310 may have a width that is substantially equal to a spacing between gate spacers 328 on opposing sides of a top portion of the gate structure. In still other examples, where the inner spacer liner layer 504 is a single, continuous layer that wraps around and is in contact with three sides (top side, bottom side, and one lateral side) of the inner spacer core layer 506 (e.g., as in the semiconductor devices 1200 and 1300 shown in FIG. 12 and FIG. 13, respectively), the gate structure disposed between adjacent epitaxial layers 310 may also have a width that is substantially equal to a spacing between gate spacers 328 on opposing sides of a top portion of the gate structure. In various embodiments, the semiconductor device 1400 may also include other features, such as described above.

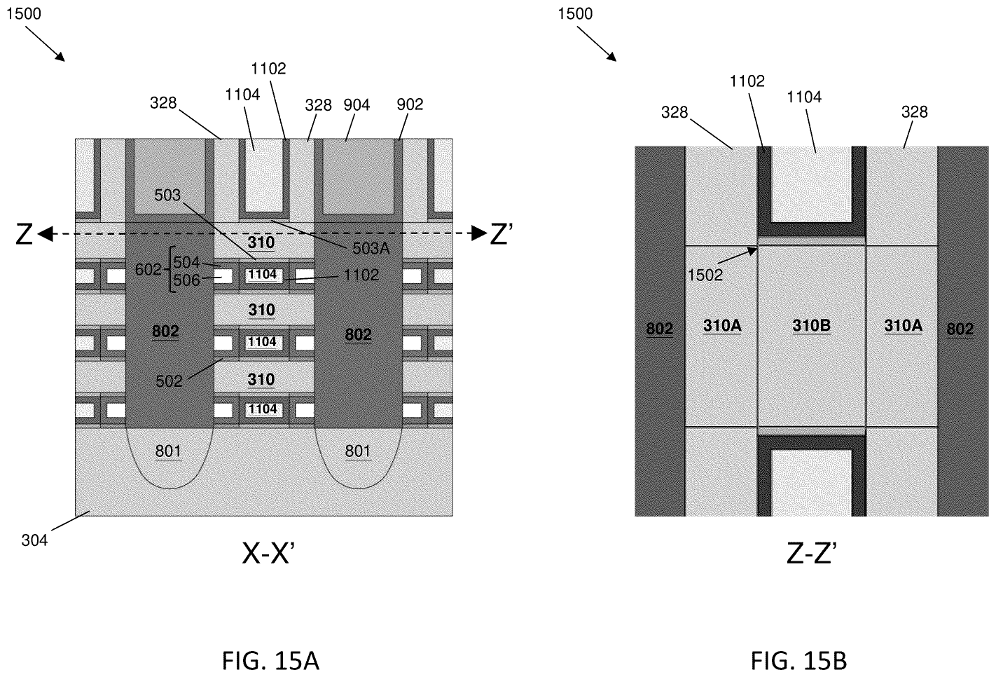

Referring to FIG. 15A and FIG. 15B, illustrated therein is an embodiment of a semiconductor device 1500, similar to the semiconductor devices 300, 1200, 1300, 1400, discussed above. In particular, FIG. 15A illustrates a cross-sectional view of the semiconductor device 1500 along a plane substantially parallel to the plane defined by section X-X′ of FIG. 1, and FIG. 15B illustrates a top-down cross-sectional view of the semiconductor device 1500 along a plane substantially parallel to the plane defined by section Z-Z′ of FIG. 15A. For clarity of discussion, the semiconductor device 1500 is shown and described using like reference numbers to indicate like features, such as used above in the discussion of the semiconductor devices 300, 1200, 1300, 1400.

The embodiment of the semiconductor device 1500 is largely the same as the embodiment of the semiconductor device 1200, discussed above. However, in contrast to the offset ‘O1’ of the semiconductor device 1200 and as shown in FIG. 15B, the semiconductor device 1500 does not have any offset (or change in width, or bow tie structure) of a dimension of the epitaxial layers 310 in the Y-direction at an interface 1502 between the portion of the epitaxial layers 310A underneath the gate spacers 328 and the portion of the epitaxial layers 310B underneath the gate structure (e.g., the gate dielectric 1102 and the metal layer 1104). In various embodiments, the semiconductor device 1500 may also include other features, such as described above.

With respect to the description provided herein, disclosed are multi-gate device structures (e.g., such as a GAA transistor structures), and related methods, where the sheet formation process is performed before formation of inner spacers, leaving gaps between adjacent Si channel layers empty after removal of the dummy layers. After the sheet formation process, the inner spacers may be formed and the source/drain features may be formed in the source/drain regions. Thereafter, the dummy gate is removed and a high-K/metal gate structure may then be formed over the Si channel layers and in the gaps between adjacent ones of the Si channel layers. Thus, embodiments of the present disclosure provide for sheet formation from a lateral direction towards source/drain regions instead of from a vertical direction towards the dummy gate (e.g., as in existing implementations). Aspects of the present disclosure provide various advantages including reduced loss of sheet width (of the Si channel layers) or wider sheet width (of the Si channel layers), increased strain in P-type transistor channels (leading to higher drive current), reduced bow tie-shape of the channels, reduced risk of metal gate protrusion (also leading to increased drive current), and less Nd effect for N-type transistors. Those of skill in the art will readily appreciate that the methods and structures described herein may be applied to a variety of other semiconductor devices and circuits to advantageously achieve similar benefits from such other devices and circuits without departing from the scope of the present disclosure. For example, GAA devices fabricated in accordance with the methods described herein may be used to form other types of devices and circuits such as memory devices (e.g., such as SRAM, DRAM, etc.), logic circuits, or other types of electronic devices and/or circuits.

Thus, one of the embodiments of the present disclosure described a semiconductor device including a plurality of nanosheets stacked over a substrate, a source/drain feature adjacent to the plurality of nanosheets, and a gate structure disposed over the plurality of nanosheets and between adjacent ones of the plurality of nanosheets, where gate spacers are disposed over sidewalls of opposing sides of a top portion of the gate structure. In some embodiments, the semiconductor device further includes inner spacers interposing lateral ends of adjacent ones of the plurality of nanosheets in a first direction and interposing portions of the gate structure and the source/drain feature in a second direction perpendicular to the first direction. In some embodiments, each of the inner spacers includes a core layer and a liner layer disposed on a top surface and a bottom surface of the core layer. In some embodiments, there is a first offset of a first dimension of the plurality of nanosheets in a third direction, perpendicular to the first direction and the second direction, at a first interface between portions of the plurality of nanosheets underneath the gate spacers and portions of the plurality of nanosheets underneath the top portion of the gate structure.

In another of the embodiments, discussed is a semiconductor device that includes a plurality of semiconductor channel layers stacked over a substrate in a first direction, source/drain features adjacent to and on either side of the plurality of semiconductor channel layers, a gate structure disposed between adjacent ones of the plurality of semiconductor channel layers, and inner spacers interposing lateral ends of adjacent ones of the plurality of semiconductor channel layers in the first direction and interposing the gate structure and the source/drain features in a second direction perpendicular to the first direction. In some embodiments, each of the inner spacers includes a core layer and a liner layer disposed on a top surface and a bottom surface of the core layer. In some embodiments, there is a first offset of a first dimension of the plurality of semiconductor channel layers in the first direction at a first interface between the inner spacers and the gate structure.

In yet another of the embodiments, discussed is a method including performing a dummy layer recess process to laterally etch ends of a plurality of dummy layers that interpose a plurality of semiconductor channel layers to form recesses along a sidewall of a trench disposed in a source/drain region. In some embodiments, the method further includes after performing the dummy layer recess process, performing a channel layer release process to selectively remove the plurality of dummy layers and form gaps between adjacent ones of the plurality of semiconductor channel layers. In some embodiments, the method further includes after performing the channel layer release process, forming inner spacers within the recesses, where the inner spacers include a core layer and a liner layer disposed on a top surface and a bottom surface of the core layer. In some embodiments, the method further includes after forming the inner spacers, forming portions of a gate structure within the gaps, where gate spacers are disposed over sidewalls of opposing sides of a top portion of the gate structure. In some embodiments, the inner spacers interpose lateral ends of adjacent ones of the plurality of semiconductor channel layers in a first direction and interpose the portions of the gate structure and the source/drain region in a second direction perpendicular to the first direction. In some embodiments, there is an offset of a dimension of the plurality of semiconductor channel layers in a third direction, perpendicular to the first direction and the second direction, at an interface between portions of the plurality of semiconductor channel layers underneath the gate spacers and portions of the plurality of semiconductor channel layers underneath the top portion of the gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of nanosheets stacked over a substrate;
a source/drain feature adjacent to the plurality of nanosheets;
a gate structure disposed over the plurality of nanosheets and between adjacent ones of the plurality of nanosheets, wherein gate spacers are disposed over sidewalls of opposing sides of a top portion of the gate structure; and
inner spacers interposing lateral ends of adjacent ones of the plurality of nanosheets in a first direction and interposing portions of the gate structure and the source/drain feature in a second direction perpendicular to the first direction;
wherein each of the inner spacers includes a core layer and a liner layer disposed on a top surface and a bottom surface of the core layer; and
wherein there is a first offset of a first dimension of the plurality of nanosheets in a third direction, perpendicular to the first direction and the second direction, at a first interface between portions of the plurality of nanosheets underneath the gate spacers and portions of the plurality of nanosheets underneath the top portion of the gate structure.

2. The semiconductor device of claim 1, wherein the liner layer is further disposed on a lateral side of the core layer, and wherein the portions of the gate structure are in contact with the liner layer disposed on the lateral side of the core layer.

3. The semiconductor device of claim 1, wherein the portions of the gate structure are in contact with a lateral side of the core layer.

4. The semiconductor device of claim 1, wherein the first offset is in a range between about 0.2-1.5 nm.

5. The semiconductor device of claim 1, wherein the liner layer has a thickness in a range between about 0.2-1 nm, and wherein the core layer has a thickness in a range between about 0.2-0.8 nm.

6. The semiconductor device of claim 1, wherein the liner layer includes silicon oxide (SiOx), silicon germanium oxide (SiGeOx), silicon nitride (SiN), silicon carbonitride (SiCN), or silicon carbon oxynitride (SiCON).

7. The semiconductor device of claim 1, wherein the core layer includes silicon oxide (SiOx), silicon nitride (SiN), silicon carbonitride (SiCN), or silicon carbon oxynitride (SiCON).

8. The semiconductor device of claim 1, wherein both the liner layer and the core layer have a dielectric constant ‘k’ in a range between about 4-7.

9. The semiconductor device of claim 1, wherein the liner layer has a first dielectric constant ‘k’ in a range between about 3-6, and wherein the core layer has a second dielectric constant ‘k’ in a range between about 4-7.

10. The semiconductor device of claim 1, wherein there is a second offset of a second dimension of the plurality of nanosheets in the first direction at a second interface between the inner spacers and the gate structure.

11. The semiconductor device of claim 10, wherein the second offset is in a range between about 0.2-1.5 nm.

12. The semiconductor device of claim 1, wherein portions of the gate structure between adjacent ones of the plurality of nanosheets have a width that is greater than a spacing between the gate spacers disposed on the opposing sides of the top portion of the gate structure.

13. A semiconductor device, comprising:
a plurality of semiconductor channel layers stacked over a substrate in a first direction;
source/drain features adjacent to and on either side of the plurality of semiconductor channel layers;
a gate structure disposed between adjacent ones of the plurality of semiconductor channel layers; and
inner spacers interposing lateral ends of adjacent ones of the plurality of semiconductor channel layers in the first direction and interposing the gate structure and the source/drain features in a second direction perpendicular to the first direction;
wherein each of the inner spacers includes a core layer and a liner layer disposed on a top surface and a bottom surface of the core layer; and
wherein there is a first offset of a first dimension of the plurality of semiconductor channel layers in the first direction at a first interface between the inner spacers and the gate structure.

14. The semiconductor device of claim 13, wherein gate spacers are disposed on sidewalls of opposing sides of a top portion of the gate structure, and wherein there is a second offset of a second dimension of the plurality of semiconductor channel layers in a third direction, perpendicular to the first direction and the second direction, at a second interface between portions of the plurality of semiconductor channel layers underneath the gate spacers and portions of the plurality of semiconductor channel layers underneath the top portion of the gate structure.

15. The semiconductor device of claim 14, wherein the first offset and the second offset are in a range between about 0.2-1.5 nm.

16. The semiconductor device of claim 13, wherein the liner layer is further disposed on a lateral side of the core layer, and wherein the gate structure is in contact with the liner layer disposed on the lateral side of the core layer.

17. The semiconductor device of claim 13, wherein the gate structure is in contact with a lateral side of the core layer.

18. The semiconductor device of claim 13, wherein the gate structure disposed between adjacent ones of the plurality of semiconductor channel layers has a width that is greater than a spacing between gate spacers disposed on sidewalls of opposing sides of a top portion of the gate structure.

19. A method, comprising:
performing a dummy layer recess process to laterally etch ends of a plurality of dummy layers that interpose a plurality of semiconductor channel layers to form recesses along a sidewall of a trench disposed in a source/drain region;
after performing the dummy layer recess process, performing a channel layer release process to selectively remove the plurality of dummy layers and form gaps between adjacent ones of the plurality of semiconductor channel layers;
after performing the channel layer release process, forming inner spacers within the recesses, wherein the inner spacers include a core layer and a liner layer disposed on a top surface and a bottom surface of the core layer; and
after forming the inner spacers, forming portions of a gate structure within the gaps, wherein gate spacers are disposed over sidewalls of opposing sides of a top portion of the gate structure;
wherein the inner spacers interpose lateral ends of adjacent ones of the plurality of semiconductor channel layers in a first direction and interpose the portions of the gate structure and the source/drain region in a second direction perpendicular to the first direction; and
wherein there is an offset of a dimension of the plurality of semiconductor channel layers in a third direction, perpendicular to the first direction and the second direction, at an interface between portions of the plurality of semiconductor channel layers underneath the gate spacers and portions of the plurality of semiconductor channel layers underneath the top portion of the gate structure.

20. The method of claim 19, further including prior to performing the channel layer release process, forming a surface film, within the trench and within the recesses, on exposed surfaces of the plurality of semiconductor channel layers and the plurality of dummy layers.
